(19) United States
(12) Patent Application Publication
(10) Pub. No.: US 2025/0290572 A1
(43) Pub. Date: Sep. 18, 2025

(54) PRESSURE EQUALISATION DEVICE FOR A HOUSING

(71) Applicant: Parker Hannifin EMEA S.à.r.l., Etoy (CH)

(72) Inventor: Stefan REICHLE, Bietigheim-Bissingen (DE)

(73) Assignee: Parker Hannifin EMEA S.à.r.l., Etoy (CH)

(21) Appl. No.: 19/224,987

(22) Filed: Jun. 2, 2025

Related U.S. Application Data
(63) Continuation of application No. PCT/EP2023/084800, filed on Dec. 7, 2023.

(30) Foreign Application Priority Data
Dec. 8, 2022 (DE) 10 2022 132 645.4

(51) Int. Cl. F16K 15/14

(52) U.S. Cl. CPC F16K 15/145

(57) ABSTRACT

The present disclosure relates to a pressure equalization device for a housing, having a base body with an inner surface and an outer surface, which is configured at least partially as a hollow cylinder, wherein the base body comprises, at its first base surface, a gas passage opening on the housing side, and at its lateral surface, at least one gas pressure relief opening, and a housing seal arranged on the outer surface of the base body in a circumferential direction and comprising a first sealing region and a second sealing region. The first sealing region of the housing seal, in a state in which the pressure equalization device is mounted in the housing, is in contact with the housing and the lateral surface of the housing and seals the housing with respect to the pressure equalization device. The second sealing region completely covers the gas pressure relief opening, and when a pressure difference between the internal pressure on the inner surface of the base body and the external pressure on the outer surface of the base body exceeds a threshold value, is elastically deformable outward in the radial direction and thereby providing a flow-conducting connection between the inner surface and outer surfaces through the gas pressure relief opening.

### CROSS REFERENCE TO RELATED APPLICATIONS

This application is a continuation of international patent application PCT/EP2023/084800, filed on Dec. 7, 2023, designating the U.S., which international patent application has been published in German language and claims priority from German patent application DE 10 2022 132 645.4, filed on Dec. 8, 2022. The entire contents of this priority application is incorporated herein by reference.

### BACKGROUND

The present disclosure relates to a pressure equalization device for a housing, as well as a housing comprising such a pressure equalization device (generally also referred to as a valve).

A pressure equalization device for a housing is known from DE 10 2017 003 360 B3. This pressure equalization device comprises an inner side, an outer side and a grid-shaped cage with a gas passage opening, wherein the gas passage opening connects the inner side and the outer side in a flow-conducting manner as required depending on the differential pressure and is limited in the direction of its flowability by an inner and an outer edge, wherein the gas passage opening is covered by a gas-permeable membrane and wherein the membrane is configured as a nonwoven composite part and comprises at least one nonwoven layer. A pressure relief valve configured as burst protection is assigned to the membrane in a functional parallel circuit.

The pressure relief valve comprises a circular ring-shaped screen made of an elastomeric material, convexly curved towards the outer side, the inner circumference of which essentially corresponds to the outer edge, the inner circumference sealingly contacting the membrane in the direction of flow on the side facing the outer side. The inner circumference is supported tightly on the outer circumference of the membrane in order to prevent a flow short circuit during the intended use of the pressure equalization device in the contact area.

The screen comprises an outer circumference configured as a sealing lip, wherein the sealing lip sealingly contacts a sealing surface of the cage under elastic prestress, wherein the membrane and the screen together spatially separate the inner and outer sides from one another and wherein the sealing lip can be lifted off the sealing surface and brought into the open position for emergency degassing of the inner side and to provide a flow-conducting connection between the inner and outer sides. If the pressure on the inner side of the pressure equalization device exceeds a predetermined threshold value, which is below the burst pressure of the housing, the sealing lip of the screen lifts off the sealing surface of the cage for emergency degassing until the pressure falls below the critical threshold value again.

The convexly curved screen is relatively long and is moved like a lever during emergency degassing, causing the sealing lip to lift off the sealing surface of the cage. Over the course of time, the force to be applied changes due to wear and service life, so that the predetermined threshold value also changes over time. The desired and pre-set behavior for ensuring emergency degassing thus changes, so that emergency degassing sometimes only occurs after some time at a higher pressure on the inner side or, for example, if the prestress of the screen decreases, emergency degassing even occurs at a lower pressure.

### SUMMARY

Against this background, the present disclosure is based on the problem of creating a pressure equalization device for a housing that avoids the disadvantages of the pressure equalization device known and also ensures the same reliable emergency degassing function with set behavior over a long period of time.

According to one aspect of the present disclosure, a pressure equalization device for a housing is provided, comprising
a base body having an inner surface and an outer surface, the base body being at least partially configured as a hollow cylinder, wherein the base body comprises, at its first base surface, a gas passage opening on the housing side, and at its lateral surface, at least one gas pressure relief opening, and
a housing seal arranged on the outer surface of the base body in a circumferential direction and comprising a first sealing region and a second sealing region, wherein the first sealing region of the housing seal, in a state in which the pressure equalization device is mounted in the housing, is in contact with the housing and the lateral surface of the housing and seals the housing with respect to the pressure equalization device and the second sealing region completely covers the gas pressure relief opening, and

wherein the second sealing region of the housing seal, when a pressure difference between the internal pressure on the inner surface of the base body and the external pressure on the outer surface of the base body exceeds a threshold value, is elastically deformable outward in the radial direction and thereby providing a flow-conducting connection between the inner surface and outer surfaces through the gas pressure relief opening.

According to a further aspect of the present disclosure, a housing comprising such a pressure equalization device is provided.

Preferred embodiments of the disclosure are defined in the dependent claims.

The disclosure is based on the idea of arranging and configuring the housing seal, which ensures emergency degassing, in a completely different way. In particular, the housing seal does not comprise a long lever arm like the screen used in the known pressure equalization device for emergency degassing and may therefore also wear significantly less. Moreover, the housing seal is in contact with the outside of the base body, so that the radial forces required for the deformation of a part of the housing seal for emergency degassing can be defined much better and the housing seal is also better held on the base body. Overall, the housing seal used according to the disclosure thus shows a significantly more stable and better long-term behavior with regard to emergency degassing. In addition, the proposed housing seal requires fewer or simpler components, which also reduces assembly costs.

In a preferred embodiment, it is provided that the base body is closed at its second base surface and that a circumferential projection is arranged on the outer surface of the base body in the area of the second base surface, which comprises a larger outer diameter than the housing seal. This ensures protection against external soiling or damage (for example by cleaning with a high-pressure jet) on the side of the second base surface. Additionally, the circumferential projection also protects the housing seal.

In an alternative embodiment, the base body comprises a gas passage opening on its second base surface, which is completely covered by a gas-permeable membrane that allows gas exchange even when the pressure difference between the internal pressure and external pressure is below the threshold value. At lower pressure differences between internal and external pressure, the membrane provides a gas passage for pressure equalization in both directions, i.e. from outside to inside or from inside to outside, in each case in the direction of the lower pressure level. Only at a higher pressure, when the pressure equalization through the membrane is no longer sufficient, or in the event of a very rapid pressure increase, does the housing seal open and thus enable emergency degassing through the gas pressure relief opening in the lateral surface of the housing. In the direction from the outside to the inside, on the other hand, emergency degassing is generally not possible, as the housing seal may not open to an external pressure that is higher than the internal pressure.

In this embodiment, a cover may also be provided that completely covers the membrane on the outer surface and comprises a larger outer diameter than the housing seal. This cover provides the protection described above against external soiling or damage, in particular to the membrane.

The cover may, for example, comprise two cover plates, wherein a first cover plate facing the membrane comprises a central opening which allows gas to pass from and to the membrane, and wherein the second cover plate spaced from the first cover plate is closed, in particular completely closed, at least in the area opposite the central opening of the first cover plate. In particular, spacer ribs may also be arranged between the cover plates, between which gas can flow from and to the membrane. The second (outer) cover plate provides the protection described above against external contamination or damage. Escaping gas is also deflected by this cover plate and flows between the cover plates in a radial direction to the outside. The escaping gas may then be diverted vertically upwards through the surrounding protective ring or installation space. The at least partial radial deflection thus provides additional protection for the membrane.

In a further embodiment, it is provided that the base body comprises in its lateral surface a plurality of gas pressure relief openings extending in the circumferential direction, all of which are covered by the second sealing region of the housing seal. Preferably, the gas pressure relief openings are slot-shaped and comprise essentially the same distance from the first base surface. This ensures optimum and rapid gas passage in the event of emergency degassing. The size and shape of the gas pressure relief openings or slots are preferably based on the cross-section required to vent the desired amount of gas per time interval. Instead of slots, the gas pressure relief openings may also comprise larger rectangular, oval or round (or other) shapes.

Preferably, the housing seal is ring-shaped and comprises an L-shaped cross-section. A first, in particular shorter, leg of the housing seal forms the first sealing region, which is in contact with a circumferential retaining projection attached to the lateral surface of the base body. A second, particularly longer leg of the housing seal forms the second sealing region, which is in contact with the lateral surface of the base body and completely covers the gas pressure relief opening and which, when the pressure difference between the internal pressure on the inner surface of the base body and the external pressure on the outer surface of the base body exceeds a threshold value, tilts relative to the first leg. This configuration provides a reliable function and enables the housing seal to be fixed precisely and permanently to the base body. In particular, the L-shaped configuration prevents the housing seal from slipping in a radial direction.

In the area of the first base surface of the base body, fastening means may also be arranged for detachable fastening in or on an installation opening of the housing. For example, the fastening means may take the form of a screw or snap connection. This allows the pressure equalization device to be attached easily, quickly and securely to the housing, for example in a hole in the housing wall, or to the housing without the need for additional retaining means (e.g. screwing, welding, soldering, etc.).

In a further embodiment, it is provided that the base body is configured, at least partially, as a straight hollow cylinder with a circular cross-section. In principle, however, the base body may also have a different cross-section, e.g. an angular or oval cross-section, and may have a curved or bent shape in the axial direction. Moreover, the diameter does not necessarily remain constant in the axial direction, but may change in the axial direction, e.g. tapering in a conical shape or changing in steps.

In a further embodiment, the pressure equalization device comprises a protective body which encloses the housing seal and at least partially the base body in the circumferential direction. Preferably, the protective body is annular in shape and comprises at least one further gas pressure relief opening (preferably extending in the circumferential direction) in its lateral surface and/or between the lateral surface and the second base surface of the base body. Such a protective body, for example in the form of a protective ring, is particularly advantageous when the pressure equalization device is installed in a thin housing wall. In such a case, the pressure equalization device sits on the housing surface and is not mounted in a recessed hole. In this case, the housing may not serve as a splash guard, as in the case where the pressure equalization device is inserted into a recessed hole. The additional protective body thus takes over the missing protection to the outside. The escaping pressure can then be discharged upwards and/or sideways without the risk of contamination or damage, for example by a jet of water from outside, which cannot then hit the housing seal directly.

It is understood that the above-mentioned features and those to be explained below can be used not only in the combination indicated in each case, but also in other combinations or on their own, without departing from the scope of the present disclosure.

### BRIEF DESCRIPTION OF THE DRAWINGS

Exemplary embodiments of the disclosure are shown in the following drawings and are explained in more detail in the following description. It shows:

FIG. 1 a cross-section through a first embodiment of the pressure equalization device according to the disclosure when mounted in a housing;

FIG. 2 a cross-section through a second embodiment of the pressure equalization device according to the disclosure;

FIG. 3 a cross-section through the second embodiment of the pressure equalization device according to the disclosure in a first operating state;

FIG. 4 a cross-section through the second embodiment of the pressure equalization device according to the disclosure in a second operating state;

FIG. 5 a perspective external view of the second embodiment of the pressure equalization device according to the disclosure;

FIG. 6 a cross-section of a third embodiment of the pressure equalization device according to the disclosure;

FIG. 7 a cross-section of the pressure equalization device shown in FIG. 6 when mounted in a housing; and

FIG. 8 a partial cross-section through a fourth embodiment of the pressure equalization device according to the disclosure in a state mounted on a housing.

### DESCRIPTION OF PREFERRED EMBODIMENTS

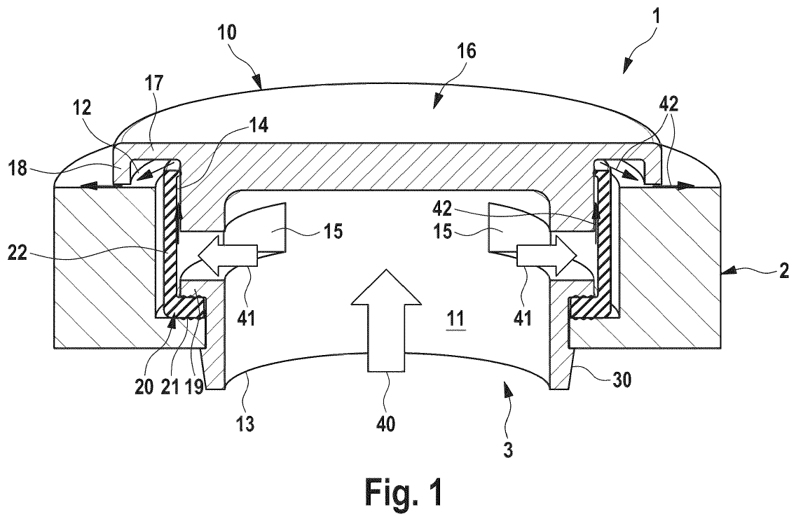

FIG. 1 shows a cross-section through a first embodiment of the pressure equalization device 1 according to the disclosure (alternatively also referred to as a valve) when mounted in a housing 2. For this purpose, the housing 2 comprises an installation opening 3, for example in the form of a hole, in which the pressure equalization device 1 may be mounted, for example by inserting, clipping in, snapping in or screwing in.

The pressure equalization device 1 comprises a base body 10 with an inner surface 11 and an outer surface 12, which is configured as a hollow cylinder, at least partially. On its first base surface 13, the base body 10 comprises a gas passage opening on the housing side, through which gas may flow from the interior of the housing 2 into the interior of the base body 10, as indicated by the arrow 40. In its lateral surface 14, the base body 10 comprises at least one gas pressure relief opening 15, through which gas may flow from the interior of the base body into the outer area in the event of emergency degassing, as indicated by the arrows 41. The base body 10 is configured in one piece in the present case, but may alternatively be constructed in several parts.

The pressure equalization device 1 further comprises a housing seal 20, which is arranged on the outer surface 12 of the base body 10 in the circumferential direction and comprises a first sealing region 21 and a second sealing region 22. When the pressure equalization device 1 is mounted in the housing 2, as shown in FIG. 1, the first sealing region 21 of the housing seal 20 is in contact with the housing 2 and externally with the lateral surface 14 of the base body 10 and seals the housing 2 with respect to the pressure equalization device 1.

The second sealing region 22 completely covers the gas pressure relief opening 15. When the pressure difference between the inner pressure on the inner surface 11 of the base body 10 and the outer pressure on the outer surface 12 of the base body 10 exceeds a threshold value, the second sealing region 22 of the housing seal 20 deforms elastically in a radial outward direction, thereby providing a flow-conducting connection between the inner surface 11 and the outer surface 12 through the gas pressure relief opening 15, as indicated by the arrows 42 (the elastically deformed second sealing region 22 is not shown here).

In the embodiment shown, the base body 10 is closed at its second base surface 16, for example in the form of a closed lid. In the area of the second base surface 16, a circumferential projection 17 is arranged on the outer surface 15 of the base body 10, which comprises a larger outer diameter than the housing seal 20. This protects both the base body 10 and the housing seal 20 from soiling or damage, for example by the water jet of a high-pressure cleaner. The projection 17 may comprise an edge 18 that is curved or folded back towards the housing 1, so that only a small gap remains between the housing and the edge 18.

In the exemplary embodiment shown, the base body comprises in its lateral surface several (in the present case two) gas pressure relief openings 15 extending in the circumferential direction, all of which are covered by the second sealing region 22 of the housing seal 20. The gas pressure relief openings 15 are slot-shaped and comprise essentially the same distance from the first base surface 13.

In the embodiment shown, the housing seal 20 is ring-shaped and comprises an L-shaped cross-section. The first sealing region 21 is formed by a first (preferably shorter) leg of the housing seal. This leg is in contact with a circumferential retaining projection 19 attached to the lateral surface 14 of the base body 10. The second sealing region 22 is formed by a second (preferably longer) leg of the housing seal 20, which is in contact with the lateral surface 14 of the base body 10 and completely covers the gas pressure relief opening 15. If the pressure difference between the inner pressure on the inner surface 11 of the base body 10 and the outer pressure on the outer surface 12 of the base body 10 exceeds a threshold value, the second leg 22 tilts relative to the first leg 21.

The threshold value at which the emergency degassing should start can be set by various parameters, in particular the choice of material for the housing seal 20, the thickness of the housing seal 20 (in the radial direction), and/or the size and position of the gas pressure relief opening 15. In some applications, the threshold value is typically in a range of approx. 0.05 to 0.3 bar, but is ultimately dependent on the application. The area of the long leg of the L-shaped housing seal may also be decisive for setting the threshold value, as well as the prestress/overlap of the long leg between the contact point of the housing seal and the lateral surface of the housing.

As already mentioned above, fastening means 30 are arranged in the region of the first base surface 13 of the base body 10 for detachable fastening in or on an installation opening 3 of the housing 2. In the present case, the fastening means 30 are configured as a circumferential snap connection (e.g. as an installation clip). However, other fastening means, for example in the form of a screw connection, may also be provided in order to ensure simple and secure mounting, which should preferably also be detachable again.

In the exemplary embodiment shown, the base body is configured, at least partially, as a straight hollow cylinder with a circular cross-section. The cross-section in the area of the gas pressure relief opening 15 is larger than in the area of the installation opening 3, in particular in order to form the retaining projection 19 described above. In this area, the diameter of the installation space in the housing is also larger than the diameter of the installation opening 3, so that there is sufficient space for the second sealing region 22 of the housing seal 20 to move outwards in the radial direction in the event of emergency degassing. Above the gas pressure relief opening 15, the wall cross-section of the housing may remain the same or be smaller.

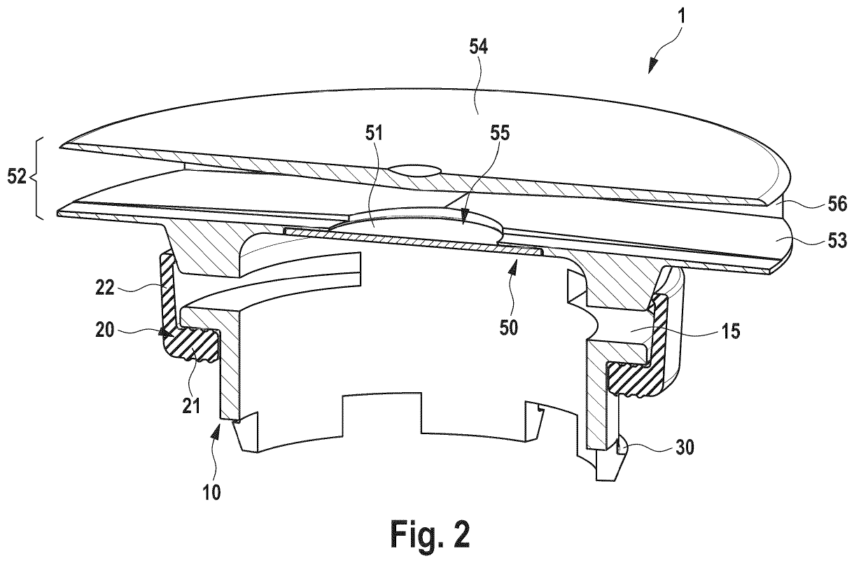

FIG. 2 shows a cross-section of a second embodiment of the pressure equalization device 1 according to the disclosure. The basic structure of the base body 10 and the housing seal 20 corresponds to the structure of the first embodiment shown in FIG. 1. Accordingly, the same reference signs are also used in FIG. 2. However, the base body 10 is configured differently in the area of the second base surface 16 and is not closed there, but comprises a gas passage opening 50 on the ambient side. This is completely covered by a gas-permeable membrane 51, which allows gas to pass through on both sides even if the pressure difference between the internal pressure and the external pressure is below the threshold value.

Additionally, a cover 52 is provided which completely covers the membrane 51 on the outer surface and comprises a larger outer diameter than the housing seal 20. The cover 52 has two cover plates 53, 54. The first cover plate 53 facing the membrane 51 comprises a central opening 55 which allows gas to pass from and to the membrane 51. The second cover plate 54, which is spaced from the first cover plate 53, is closed (preferably completely) at least in the area opposite the central opening 55 of the first cover plate 53. Spacer ribs 56 are arranged between the cover plates 53, 54, between which gas may flow from and to the membrane 51.

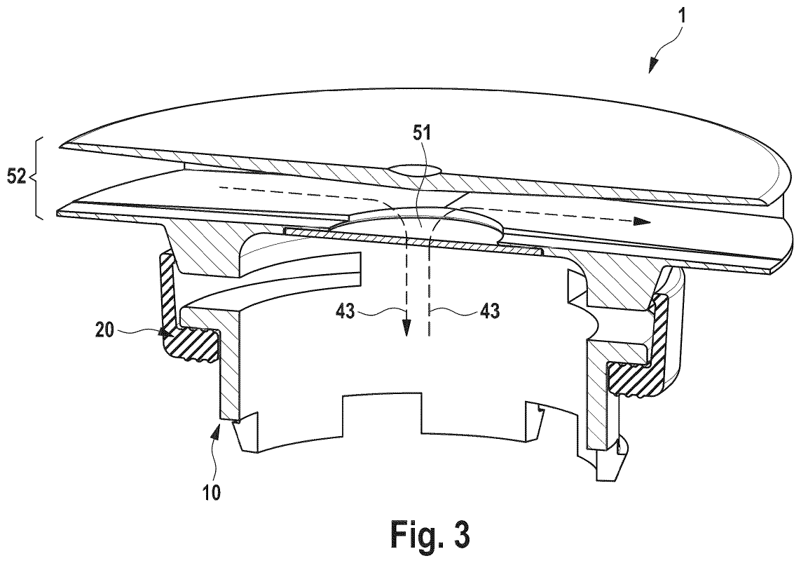

FIG. 3 shows a cross-section through the second embodiment (shown in FIG. 2) of the pressure equalization device 1 according to the disclosure in a first operating state. In this operating state, the pressure difference between the inner and outer surfaces is below the threshold value. In this operating state, the second pressure region 22 of the housing seal 20 is in contact with the lateral surface 14, so that no emergency degassing takes place. However, the pressure difference is large enough to allow pressure equalization through the membrane 51, as indicated by the arrows 43.

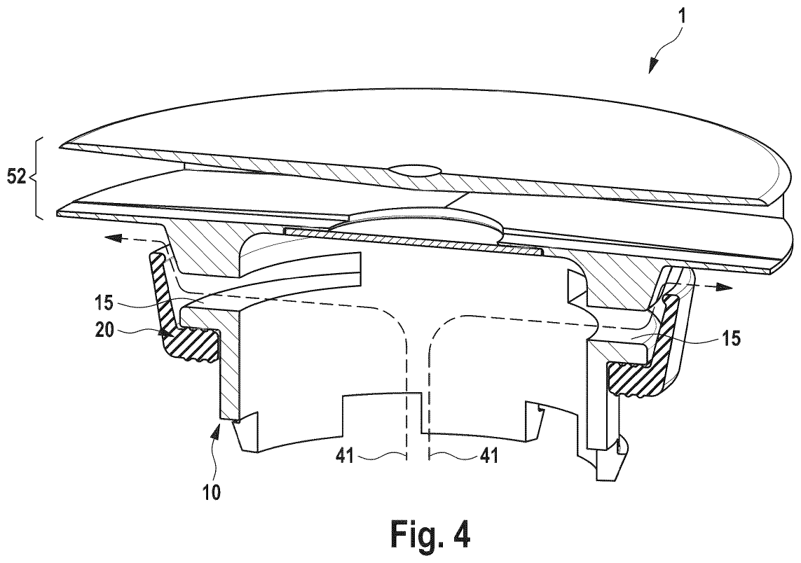

FIG. 4 shows a cross-section through the second embodiment (shown in FIG. 2) of the pressure equalization device 1 according to the disclosure in a second operating state. In this operating state, the pressure difference between the inner and outer surfaces is above the threshold value. In this operating state, the second pressure area 22 of the housing seal 20 is no longer completely in contact with the lateral surface 14, but is pressed outwards by the higher internal pressure, thereby opening the path through the gas pressure relief opening 15, so that emergency degassing takes place, as indicated by the arrows 41.

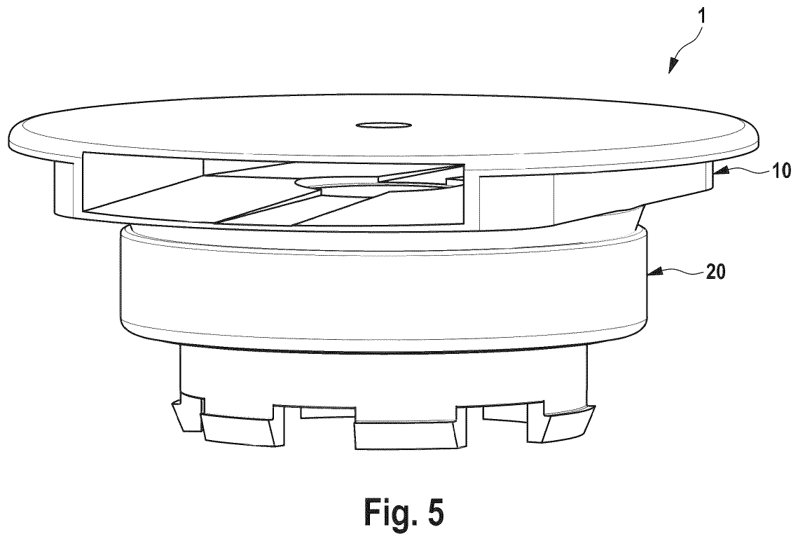

FIG. 5 shows a perspective external view of the second embodiment of the pressure equalization device 1 according to the disclosure. The housing seal 20 can be seen there, which surrounds the lateral surface of the base body almost like a ring. The housing seal may also be configured accordingly in other embodiments.

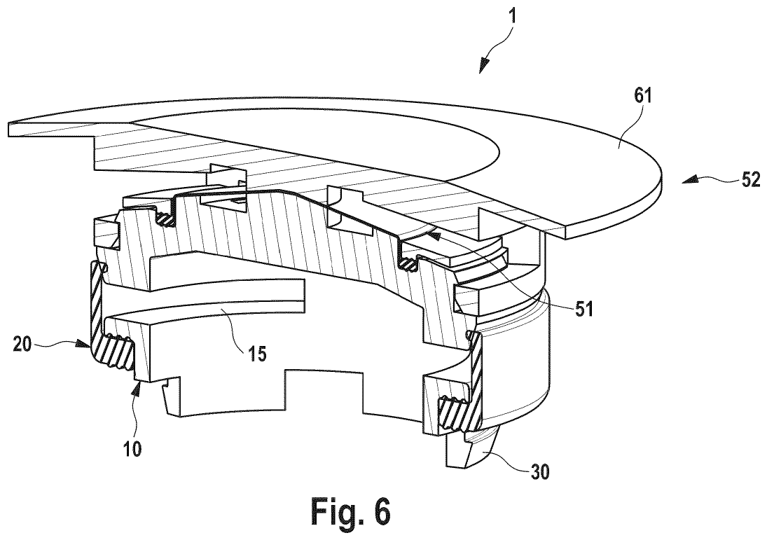

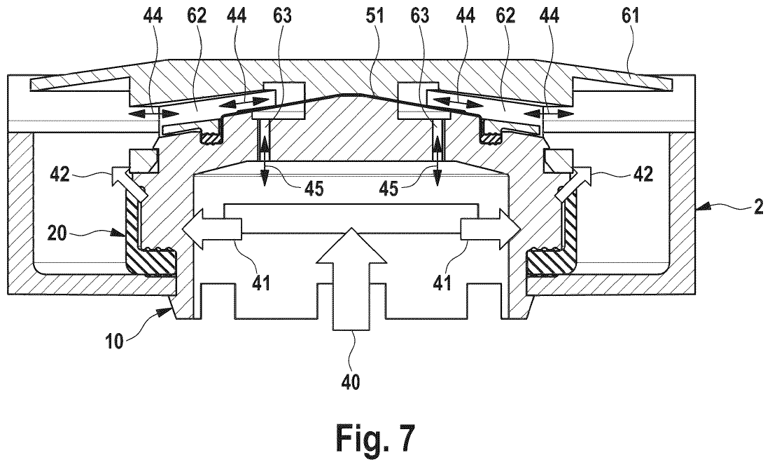

FIG. 6 shows a cross-section of a third embodiment of the pressure equalization device 1 according to the disclosure. FIG. 7 shows a cross-section of the pressure equalization device 1 shown in FIG. 6 when mounted in a housing 2. In this embodiment, the cover 60 has a slightly different configuration than the cover 52 in the second embodiment shown in FIG. 2. In particular, the cover 52 comprises only a single cover plate 61, which protrudes laterally beyond the base body 10 and the housing seal and is convexly shaped, almost like a screen. Channels 62 are formed between the cover plate 61 and the membrane 51, and channels 63 are formed between the interior of the base body 10 and the membrane 51. Through these channels 62, 63, gas exchange may take place between the inner surface 11 and the outer surface 12, as indicated by the arrows 44 and 45. The convex shape helps with vertical mounting, as it allows spray water and dirt from outside to run off more easily. With a convex shape, the membrane is preferably supported in the center and does not comprise a central hole.

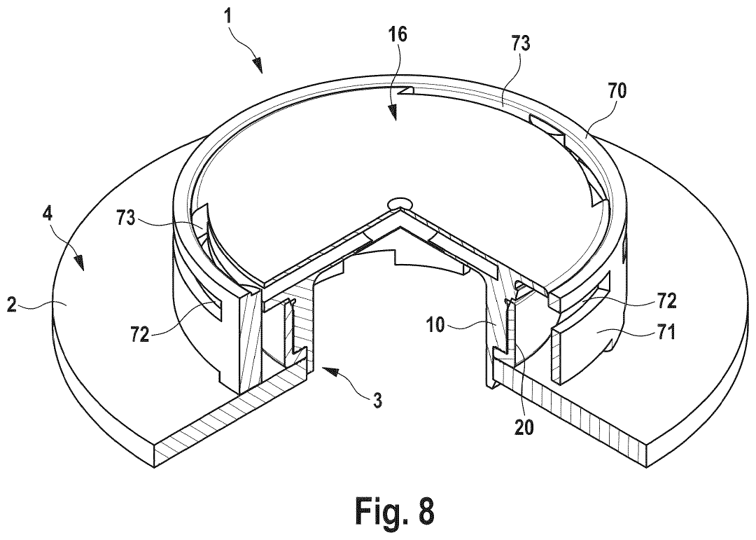

FIG. 8 shows a partial cross-section through a fourth embodiment of the pressure equalization device 1 according to the disclosure. This embodiment is primarily suitable for being mounted on the housing 2 from the outside, whereas the embodiments described above are primarily suitable for being mounted in the installation opening 3, although in the case shown in FIG. 8 the housing 2 also comprises an opening 3. Assembly may be carried out in the same or a similar manner as in the embodiments described above, i.e., such as by means of a clip, a screw connection, a bayonet lock, etc.

In this embodiment, the pressure equalization device 1 may comprise a membrane, as in the second and third embodiments, or may be configured without a membrane, as in the first embodiment. The cover may further be configured as in one of the embodiments described above.

In contrast to the embodiments described above, in this embodiment the pressure equalization device comprises a protective body 70 which surrounds the housing seal 20 and at least partially the base body 10 in the circumferential direction and which rests on the housing 1, i.e. has a larger diameter than the opening 3. Preferably, the protective body 70 is formed as a protective ring which comprises at least one gas outlet (preferably extending in the circumferential direction) in its lateral surface 71 and/or between its lateral surface 71 and the second base surface 16 of the base body 10. In the embodiment shown, a plurality of slot-shaped gas outlets 72 are provided in the lateral surface 71. Additionally, a plurality of slot-shaped gas outlets 74 are provided between the lateral surface 71 and the second base surface 16 of the base body 10, which are formed, for example, by the uppermost cover plate 54 comprising corresponding recesses at its edge in certain regions.

The protective body 70 is particularly advantageous when the pressure equalization device 1 is installed in a thin housing wall. In such a case, the pressure equalization device 1 sits on the housing surface 4 and is not mounted in a recessed hole, as in the other embodiments. In this case, the housing 2 may not serve as a splash guard, as in the embodiments described above. The additional protective body 70 thus takes over the missing protection to the outside. The escaping pressure can then be discharged upwards and/or laterally through the gas outlets 72 and 73 without contamination or damage, in particular to the housing seal 20, for example by a jet of water from outside, which may then not hit the housing seal 20 directly.

The pressure equalization device according to the disclosure thus offers various advantages over known solutions. The prestress of the screen in the known solution described above determines the opening pressure. Since the screen is made of elastomeric material, which is subject to ageing effects, a reduction in tension takes place over time, i.e. the tension in the material is reduced. The opening function of the screen is like a flap, so that any change in prestress is intensified over the length of the screen.

According to the disclosure, the housing seal is not configured as a screen, but as a hose-, tube- or ring-shaped seal. This enables better adjustment of the opening point of the valve, i.e. the threshold value above which emergency degassing should take place. This configuration of the housing seal eliminates the leverage effect, as the prestress is generated by the expansion of the inner diameter of the housing seal. Moreover, the solution according to the present disclosure results in a lower degradation of the prestressing of the housing seal and thus no or at least significantly reduced change in the opening pressure over the lifespan. The inner diameter of the housing seal, at least in the area of the sealing point/sealing nose, is smaller than the diameter of the housing on which the housing seal rests. For assembly, the housing seal is widened and thus sits on the housing with a (pre-) tension that generates the sealing force and presses the material at the sealing point.

The configuration according to the disclosure also enables a valve construction with a smaller number of parts compared to existing solutions. The simplest solution consists of only two parts. Finally, improved protection against environmental influences is also achieved compared to existing solutions. Installation in or on housing is also simple and reliable.

What is claimed is:

1. A pressure equalization device for a housing, comprising
a base body having an inner surface and an outer surface, the base body being at least partially configured as a hollow cylinder, wherein the base body comprises, at its first base surface, a gas passage opening on the housing side, and at its lateral surface, at least one gas pressure relief opening, and
a housing seal arranged on the outer surface of the base body in a circumferential direction and comprising a first sealing region and a second sealing region,
wherein the first sealing region of the housing seal, in a state in which the pressure equalization device is mounted in the housing, is in contact with the housing and the lateral surface of the housing and seals the housing with respect to the pressure equalization device and the second sealing region completely covers the gas pressure relief opening, and
wherein the second sealing region of the housing seal, when a pressure difference between the internal pressure on the inner surface of the base body and the external pressure on the outer surface of the base body exceeds a threshold value, is elastically deformable outward in the radial direction and thereby providing a flow-conducting connection between the inner surface and outer surfaces through the gas pressure relief opening.

2. The pressure equalization device according to claim 1,
wherein the base body is closed at its second base surface, and wherein a circumferential projection is arranged on the outer surface of the base body in the area of the second base surface, said projection having a larger outer diameter than the housing seal.

3. The pressure equalization device according to claim 1,
wherein the base body comprises, at its second base surface, an environment-facing gas passage opening, which is fully covered by a gas-permeable membrane that permits gas passage even when the pressure difference between internal and external pressure is below the threshold.

4. The pressure equalization device according to claim 3,
further comprising a cover which completely covers the membrane on the outer surface and has a larger outer diameter than the housing seal.

5. The pressure equalization device according to claim 4,
wherein the cover comprises two cover plates, wherein a first cover plate facing the membrane comprises a central opening that allows gas to pass to and from the membrane, and wherein a second cover plate spaced apart from the first cover plate is closed, in particular completely closed, at least in the area opposite the central opening of the first cover plate.

6. The pressure equalization device according to claim 5,
wherein spacer ribs are arranged between the cover plates, between which gas may flow to and from the membrane.

7. The pressure equalization device according to claim 1,
wherein the lateral surface of the base body comprises a plurality of gas pressure relief openings extending in the circumferential direction, all of which are covered by the second sealing region of the housing seal.

8. The pressure equalization device according to claim 7,
wherein the gas pressure relief openings are slot-shaped and comprise substantially the same distance from the first base surface.

9. The pressure equalization device according to claim 1,
wherein the housing seal is ring-shaped and has an L-shaped cross-section.

10. The pressure equalization device according to claim 9,
wherein a first, in particular shorter, leg of the housing seal forms the first sealing region, which is in contact with a circumferential retaining projection attached to the lateral surface of the base body, and
wherein a second, in particular longer, leg of the housing seal forms the second sealing region, which is in contact with the lateral surface of the base body and completely covers the gas pressure relief opening and which tilts relative to the first leg when the pressure difference between the inner pressure on the inner surface of the base body and the outer pressure on the outer surface of the base body exceeds a threshold value.

11. The pressure equalization device according to claim 1,
wherein fastening means are arranged in the area of the first base surface of the base body for detachably fastening it in or to an installation opening of the housing.

12. The pressure equalization device according to claim 11,
wherein the fastening means are configured as a screw or snap connection.

13. The pressure equalization device according to claim 1,
wherein the base body is at least partially configured as a straight hollow cylinder with a circular cross-section.

14. The pressure equalization device according to claim 1,
further comprising a protective body surrounding the housing seal and at least partially surrounding the base body in the circumferential direction.

15. The pressure equalization device according to claim 14,
wherein the protective body is ring-shaped and comprises at least one further gas pressure relief opening in its lateral surface and/or between the lateral surface and the second base surface.

16. A housing comprising a pressure equalization device according to claim 1.
